(19) United States
(12) Patent Application Publication
(10) Pub. No.: US 2026/0181783 A1
(43) Pub. Date: Jun. 25, 2026

(54) Wiring Circuit Board and Wiring Circuit Board Manufacturing Method

(71) Applicant: NITTO DENKO CORPORATION, Osaka (JP)

(72) Inventors: Yukihiro Fujibayashi, Ibaraki-shi (JP); Jun Ishii, Ibaraki-shi (JP); Tsubasa Kitamura, Ibaraki-shi (JP)

(73) Assignee: NITTO DENKO CORPORATION, Osaka (JP)

(21) Appl. No.: 19/424,979

(22) Filed: Dec. 18, 2025

(30) Foreign Application Priority Data
Dec. 19, 2024 (JP) 2024-223797

(51) Int. Cl. H05K 1/183; H05K 1/11; H05K 3/02

(52) U.S. Cl. CPC H05K 1/183; H05K 1/115; H05K 3/02; H05K 2201/09745; H05K 2201/09854; H05K 2201/10734

(57) ABSTRACT

A wiring circuit board includes a wiring structure layer having an insulating layer and a wiring layer, and a metal reinforcing layer in contact with one surface thereof, having an exposed surface opposite to the wiring structure layer and a penetrating opening for connection of a semiconductor chip to the wiring circuit board. In a cross section of the metal reinforcing layer, a line (C) connects an intersection (a) of one of two side lines of the opening and a surface line (A) of the metal reinforcing layer opposite to the wiring structure layer and an intersection (b) of the one side line and a surface line (B) of the metal reinforcing layer on the wiring structure layer side, and an angle (α) formed by the line (C) and a line (BH) of the line (B) opposite to the opening from the intersection (b) is less than 90°.

### CROSS-REFERENCE TO RELATED APPLICATIONS

This application claims priority under 35 U.S.C. 119 to Japanese Application No. 2024-223797, filed Dec. 19, 2024. The entire teachings of the above application are incorporated herein by reference.

### BACKGROUND OF THE INVENTION

### Field of the Invention

The present invention relates to a wiring circuit board, a method for manufacturing the wiring circuit board, a semiconductor package including the wiring circuit board, and an electronic device.

### Description of the Related Art

A wiring circuit board is manufactured, for example, by stacking a conductor portion such as a wiring line and various insulating layers on a base material. The conductor portion and the insulating layer are patterned by, for example, a photolithography method.

As a semiconductor device having a wiring circuit board and a semiconductor chip, for example, a semiconductor device has been proposed, the semiconductor device including: a semiconductor chip; a substrate disposed below the semiconductor chip and having a first region which is a region where the semiconductor chip is mounted and a second region which is a region where a conductor element including at least one of a circuit pattern and an electrical component is provided; and an insulating sheet covering the conductor element (see JP 2023-118943 A).

As a wiring circuit board, for example, a printed circuit board has been proposed, the printed circuit board including: a substrate including a plurality of wiring layers; a first metal post disposed on the substrate and coupled to at least a part of a wiring layer disposed on an uppermost side among the plurality of wiring layers; a second metal post disposed on the substrate and coupled to at least another part of the wiring layer disposed on the uppermost side among the plurality of wiring layers; a resist layer disposed on the substrate and embedding at least a part of each of the first metal post and the second metal post; and a metal via penetrating the resist layer on the second metal post and coupled to the second metal post (see JP 2024-18878 A).

In one embodiment of these proposed technologies, a stiffener is attached to the substrate or the printed circuit board to reduce distortion and warpage (see, for example, paragraph [0018] of JP 2023-118943 A and paragraph [0023] of JP 2024-18878 A).

A rewiring board has been proposed which is used to electrically connect a first electrical element and a second electrical element, the rewiring board including: a first insulating layer having first and second principal surfaces opposite to each other; a first terminal portion formed so as to be exposed on the first principal surface of the first insulating layer; a second terminal portion formed so as to be exposed on the second principal surface of the first insulating layer; a conductor layer connecting the first terminal portion and the second terminal portion in the first insulating layer; a metal support formed on the first principal surface of the first insulating layer and having an opening; and a second insulating layer formed on an inner surface of the opening of the metal support, the opening being provided so as to overlap the first terminal portion when viewed in a first direction perpendicular to the first principal surface of the first insulating layer, the first terminal portion being provided so as to be electrically connectable to the first electrical element through or within the opening, and the second terminal portion being provided so as to be electrically connectable to the second electrical element (see WO 2023/080097 A).

Providing a metal reinforcing layer (metal support) such as a stiffener on the surface of the wiring circuit board is effective for reinforcing (reducing warpage and distortion) the wiring circuit board. Generally, the stiffener has an opening, and a semiconductor chip is placed in the opening. In order to reinforce the wiring circuit board, the opening of the metal reinforcing layer is preferably small.

Here, the wiring circuit board where the semiconductor chip is placed in the opening of the metal reinforcing layer is placed on another substrate such as a mother board, and then sealed with a sealing resin composition in order to protect the semiconductor chip and the wiring circuit board. However, when an interval (gap) between the edge of the opening of the metal reinforcing layer and the semiconductor chip is narrow at the time of sealing, the sealing resin composition cannot sufficiently enter the gap, and voids may remain in the opening of the metal reinforcing layer after sealing. When the voids remain, the mechanical strength is weakened, which causes defects such as cracking and chipping. In this respect, the opening of the metal reinforcing layer is preferably large.

As described above, the opening of the metal reinforcing layer is preferably small from the viewpoint of reinforcing the wiring circuit board, but the opening of the metal reinforcing layer is preferably large from the viewpoint of reducing the voids at the time of sealing. Therefore, it is desirable to achieve both of these.

### SUMMARY OF THE INVENTION

An object of the present invention is to provide a wiring circuit board capable of suppressing generation of voids at the time of sealing without deteriorating an effect of reinforcing the wiring circuit board by a metal reinforcing layer, a method for manufacturing the wiring circuit board, a semiconductor package including the wiring circuit board, and an electronic device.

As a result of intensive studies to solve the above problems, the present inventors have found that the above problems can be solved, and have completed the present invention having the following gist.

That is, the present invention includes the following.
[1] A wiring circuit board including a wiring structure layer having an insulating layer and a wiring layer, and a metal reinforcing layer in contact with one surface of the wiring structure layer, wherein
a surface of the metal reinforcing layer on a side opposite to the wiring structure layer side is exposed,
the metal reinforcing layer has an opening for enabling a semiconductor chip to be connected to the wiring circuit board, the opening penetrating the metal reinforcing layer in a thickness direction, and
in a case where, in a cross section in the thickness direction of the metal reinforcing layer, which includes the opening,
a line which is a surface of the metal reinforcing layer on a side opposite to the wiring structure layer side is defined as a line (A),
a line which is a surface of the metal reinforcing layer on the wiring structure layer side is defined as a line (B),
an intersection of one side line of two side lines included in a shape of the opening and the line (A) is defined as an intersection (a), an intersection of the one side line and the line (B) is defined as an intersection (b),
a line connecting the intersection (a) and the intersection (b) is defined as a line segment (C), and
a line of the line (B) on a side opposite to the opening side with the intersection (b) as a start point is defined as a half line (BH),
an angle (α) formed by the half line (BH) and the line segment (C) is less than 90°.
[2] The wiring circuit board according to [1], wherein the angle (α) is 45° or more and less than 90°.
[3] The wiring circuit board according to [1] or [2], wherein the metal reinforcing layer has a second opening penetrating the metal reinforcing layer in the thickness direction in addition to the opening.
[4] The wiring circuit board according to [1] or [2], wherein
the metal reinforcing layer has a second opening and a third opening penetrating the metal reinforcing layer in the thickness direction in addition to the opening, and
the second opening and the third opening are formed so as to sandwich the opening in an arbitrary cross section (X) in the thickness direction of the metal reinforcing layer.
[5] The wiring circuit board according to [4], wherein in a cross section (Y) that is a cross section in the thickness direction of the metal reinforcing layer and is orthogonal to the cross section (X), the metal reinforcing layer does not have an opening penetrating the metal reinforcing layer in the thickness direction.
[6] The wiring circuit board according to [4], wherein
the metal reinforcing layer further has a fourth opening penetrating the metal reinforcing layer in the thickness direction, and
the fourth opening is formed such that a cross section (Y) in the thickness direction of the metal reinforcing layer, which is orthogonal to the cross section (X), includes the fourth opening.
[7] The wiring circuit board according to any one of [1] to [6], wherein the wiring structure layer includes an insulating layer other than the insulating layer and a wiring layer other than the wiring layer in the opening of the metal reinforcing layer.
[8] The wiring circuit board according to any one of [1] to [6], wherein the wiring structure layer does not include an insulating layer other than the insulating layer and a wiring layer other than the wiring layer in the opening of the metal reinforcing layer.
[9] A semiconductor package including the wiring circuit board according to any one of [1] to [8].
[10] An electronic device including the semiconductor package according to [9].
[11] A wiring circuit board manufacturing method for manufacturing the wiring circuit board according to any one of [1] to [8], the wiring circuit board manufacturing method including:
a step of forming the opening penetrating the metal reinforcing layer in the thickness direction in the metal reinforcing layer, wherein
the step of forming the opening includes forming the opening such that the angle (α) is less than 90°.
[12] The wiring circuit board manufacturing method according to [11], wherein the step of forming the opening includes forming the opening by wet etching such that the angle (α) is less than 90°.

According to the present invention, it is possible to provide a wiring circuit board capable of suppressing generation of voids at the time of sealing without deteriorating an effect of reinforcing the wiring circuit board by a metal reinforcing layer, a method for manufacturing the wiring circuit board, a semiconductor package including the wiring circuit board, and an electronic device.

### BRIEF DESCRIPTION OF THE DRAWINGS

FIG. 1A is a schematic diagram of an embodiment of a wiring circuit board;

FIG. 1B is a schematic diagram of an embodiment of a wiring circuit board;

FIG. 2A is a top view of another embodiment of a wiring circuit board;

FIG. 2B is a cross-sectional view of the wiring circuit board of FIG. 2A taken along line X-X;

FIG. 2C is a cross-sectional view of the wiring circuit board of FIG. 2A taken along line Y-Y;

FIG. 3A is a top view of another embodiment of a wiring circuit board;

FIG. 3B is a cross-sectional view of the wiring circuit board of FIG. 3A taken along line X-X;

FIG. 3C is a cross-sectional view of the wiring circuit board of FIG. 3A taken along line Y-Y;

FIG. 4A is a schematic diagram for explaining an example of a method for manufacturing a wiring circuit board (part 1);

FIG. 4B is a schematic diagram for explaining an example of the method for manufacturing the wiring circuit board (part 2);

FIG. 4C is a schematic diagram for explaining an example of the method for manufacturing the wiring circuit board (part 3);

FIG. 4D is a schematic diagram for explaining an example of the method for manufacturing the wiring circuit board (part 4);

FIG. 4E is a schematic diagram for explaining an example of the method for manufacturing the wiring circuit board (part 5);

FIG. 4F is a schematic diagram for explaining an example of the method for manufacturing the wiring circuit board (part 6);

FIG. 4G is a schematic diagram for explaining an example of the method for manufacturing the wiring circuit board (part 7);

FIG. 4H is a schematic diagram for explaining an example of the method for manufacturing the wiring circuit board (part 8);

FIG. 4I is a schematic diagram for explaining an example of the method for manufacturing the wiring circuit board (part 9);

FIG. 5 is a schematic diagram of another embodiment of a wiring circuit board;

FIG. 6 is a schematic diagram of another embodiment of a wiring circuit board;

FIG. 7 is a schematic diagram of another embodiment of a wiring circuit board;

FIG. 8A is a schematic diagram of another embodiment of a wiring circuit board;

FIG. 8B is a schematic diagram of another embodiment of a wiring circuit board;

FIG. 9A is a schematic diagram of an embodiment of a wiring circuit board;

FIG. 9B is a structure example of a region X of the wiring circuit board of FIG. 9A;

FIG. 9C is another structure example of the region X of the wiring circuit board of FIG. 9A;

FIG. 9D is another structure example of the region X of the wiring circuit board of FIG. 9A;

FIG. 9E is another structure example of the region X of the wiring circuit board of FIG. 9A; and

FIG. 10 is a schematic diagram of an example of a wiring circuit board to which a semiconductor chip is connected.

### DESCRIPTION OF THE EMBODIMENTS

### (Wiring Circuit Board and Method for Manufacturing Wiring Circuit Board)

A wiring circuit board of the present invention includes a wiring structure layer and a metal reinforcing layer.

The metal reinforcing layer is in contact with one surface of the wiring structure layer.

The wiring structure layer includes an insulating layer and a wiring layer. The wiring structure layer may further include a second insulating layer, a third insulating layer, a fourth insulating layer, a fifth insulating layer, a second wiring layer, a third wiring layer, a fourth wiring layer, and the like.

In the wiring circuit board, a surface of the metal reinforcing layer on a side opposite to the wiring structure layer side is exposed.

The metal reinforcing layer has an opening that enables a semiconductor chip to be connected to the wiring circuit board and that penetrates the metal reinforcing layer in a thickness direction.

In a case where, in a cross section in the thickness direction of the metal reinforcing layer, which includes the opening,
a line which is a surface of the metal reinforcing layer on a side opposite to the wiring structure layer side is defined as a line (A),
a line which is a surface of the metal reinforcing layer on the wiring structure layer side is defined as a line (B),
an intersection of one side line of two side lines included in a shape of the opening and the line (A) is defined as an intersection (a), an intersection of the one side line and the line (B) is defined as an intersection (b),
a line connecting the intersection (a) and the intersection (b) is defined as a line segment (C), and
a line of the line (B) on a side opposite to the opening side with the intersection (b) as a start point is defined as a half line (BH),
an angle (α) formed by the half line (BH) and the line segment (C) is less than 90°.

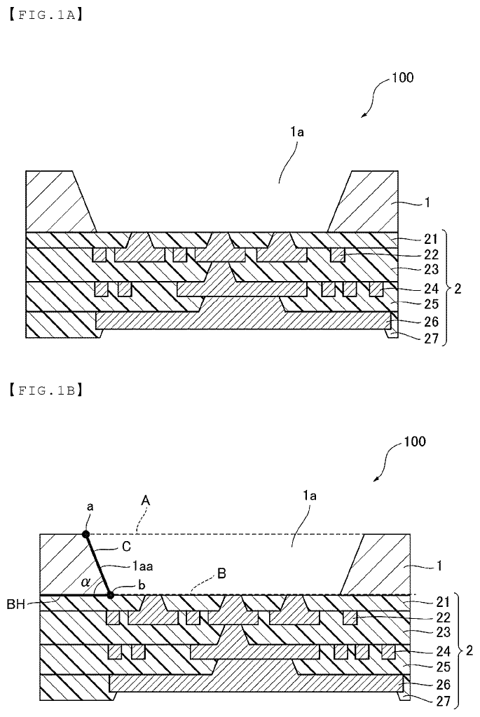

Hereinafter, an example of a wiring circuit board of the present invention will be described with reference to FIGS. 1A and 1B.

FIGS. 1A and 1B are schematic cross-sectional views of an example of the wiring circuit board.

The wiring circuit boards of FIGS. 1A and 1B have the same structure. However, in FIG. 1B, an auxiliary line for explaining an angle (α) is drawn.

A wiring circuit board 100 includes a metal reinforcing layer 1 and a wiring structure layer 2.

The metal reinforcing layer 1 is in contact with one surface of the wiring structure layer 2.

A surface of the metal reinforcing layer 1 on the side opposite to the wiring structure layer 2 side is exposed.

The metal reinforcing layer 1 has an opening 1a that enables a semiconductor chip to be connected to the wiring circuit board 100 and penetrates the metal reinforcing layer 1 in a thickness direction.

The wiring structure layer 2 includes an insulating layer 21 and a wiring layer 22. The wiring structure layer 2 further includes a second insulating layer 23, a second wiring layer 24, a third insulating layer 25, a third wiring layer 26, and a fourth insulating layer 27.

In the wiring structure layer 2, the insulating layer 21, the wiring layer 22, the second insulating layer 23, the second wiring layer 24, the third insulating layer 25, the third wiring layer 26, and the fourth insulating layer 27 are provided in this order.

The insulating layer 21 is in contact with the metal reinforcing layer 1. The wiring layer 22 has a pattern shape. The second insulating layer 23 covers the wiring layer 22 while filling gaps in the pattern of the wiring layer 22. The second wiring layer 24 has a pattern shape. The third insulating layer 25 covers the second wiring layer 24 while filling gaps in the pattern of the second wiring layer 24. The third wiring layer 26 has a pattern shape. The fourth insulating layer 27 covers the third wiring layer 26 while filling gaps in the pattern of the third wiring layer 26. On the other hand, a part of the third wiring layer 26 is exposed through a through hole of the fourth insulating layer 27.

A part of the wiring layer 22 fills a through hole of the insulating layer 21. A part of the second wiring layer 24 fills a through hole of the second insulating layer 23. A part of the third wiring layer 26 fills a through hole of the third insulating layer 25.

A part of the wiring layer 22 is in electrical contact with a part of the second wiring layer 24. A part of the second wiring layer 24 is in electrical contact with a part of the third wiring layer 26.

In the wiring circuit board 100 illustrated in FIGS. 1A and 1B, a part of the wiring layer 22 filling the through hole of the insulating layer 21 is exposed at the opening 1a of the metal reinforcing layer 1. A part of the wiring layer 22 exposed at the opening 1a is used as a terminal for connection with the semiconductor chip.

In the wiring circuit board 100 of FIGS. 1A and 1B, a cross-sectional shape of the opening 1a in the thickness direction of the metal reinforcing layer 1 is a tapered shape in which a width of the opening 1a on the surface of the metal reinforcing layer 1 on the wiring structure layer 2 side is smaller than a width of the opening 1a on the surface of the metal reinforcing layer 1 on the side opposite to the wiring structure layer 2 side. Here, the width of the opening 1a is a length in a direction orthogonal to the thickness direction of the metal reinforcing layer 1.

That is, in a case where, in a cross section in the thickness direction of the metal reinforcing layer 1, which includes the opening 1a,
a line which is a surface of the metal reinforcing layer 1 on a side opposite to the wiring structure layer 2 side is defined as a line (A),
a line which is a surface of the metal reinforcing layer 1 on the wiring structure layer 2 side is defined as a line (B),
an intersection of one side line 1aa of two side lines included in a shape of the opening 1a and the line (A) is defined as an intersection (a), an intersection of the one side line 1aa and the line (B) is defined as an intersection (b),
a line connecting the intersection (a) and the intersection (b) is defined as a line segment (C), and
a line of the line (B) on a side opposite to the opening 1a side with the intersection (b) as a start point is defined as a half line (BH),
an angle (α) formed by the half line (BH) and the line segment (C) is less than 90°.

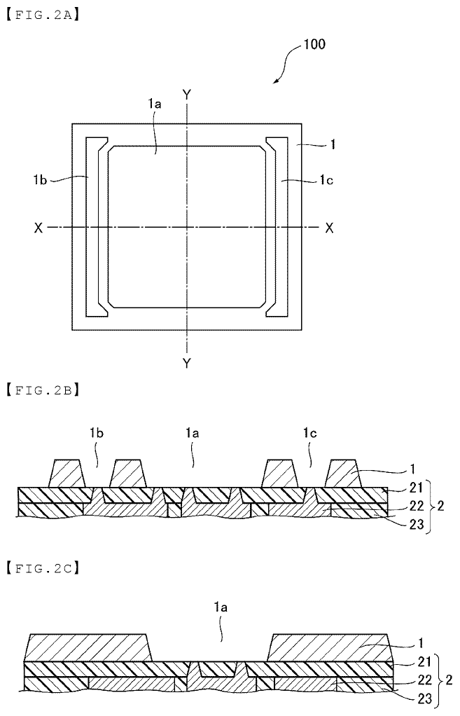

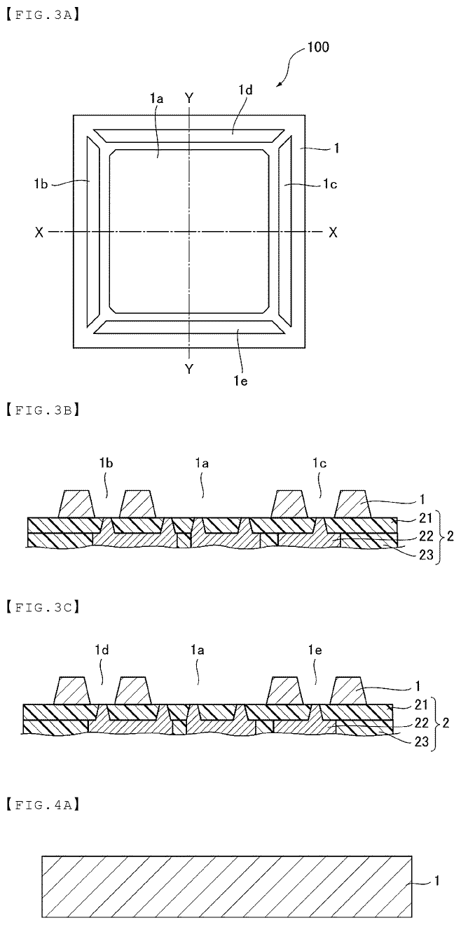

The cross section for obtaining the angle (α) is preferably a cross section orthogonal to the side of the opening (for example, a cross section taken along line X-X and a cross section taken along line Y-Y in FIGS. 2A and 3A). In a case where the shape of the opening when viewed from the thickness direction is a polygon, the cross section for obtaining the angle (α) is preferably a cross section orthogonal to a relatively long side (for example, a longest side) among all sides of the polygon. Further, the cross section for obtaining the angle (α) may be orthogonal to the side at any position of the side of the opening, but is preferably orthogonal to the side near the center of the side. As long as it can be confirmed whether or not the angle (α) is less than 90°, the side and the cross section do not need to intersect completely at 90°, and may intersect at an angle close to 90°.

As described above, in the wiring circuit board, the metal reinforcing layer 1 has a structure in which the angle (α) is less than 90°.

In this way, an opening area of the opening 1a on the surface of the metal reinforcing layer 1 on the side opposite to the wiring structure layer 2 side can be increased, so that an interval (gap) between the edge of the opening 1a of the metal reinforcing layer 1 and the semiconductor chip can be increased when the semiconductor chip is placed on the opening 1a. The opening 1a has a mortar shape. As a result, a sealing resin composition can sufficiently enter the gap, and it is possible to suppress remaining of voids in the opening 1a of the metal reinforcing layer 1 after sealing.

In addition, since the opening area of the opening 1a on the surface of the metal reinforcing layer 1 on the wiring structure layer 2 side is small, a volume of the metal portion of the metal reinforcing layer 1 can be increased. As a result, the reinforcing effect of the metal reinforcing layer 1 can be prevented from being deteriorated.

The angle (α) may be less than 90°, and the lower limit thereof is not particularly limited, but the angle (α) is preferably 45° or more, more preferably 50° or more, and particularly preferably 55° or more from the viewpoint that the opening area on the surface of the metal reinforcing layer on the side opposite to the wiring structure layer side does not become too large, and as a result, it is possible to prevent the volume of the metal portion of the metal reinforcing layer from becoming small.

The angle (α) may be less than 90°, and is preferably 85° or less, more preferably 80° or less, and particularly preferably 75° or less from the viewpoint of being able to increase the interval (gap) between the edge of the opening of the metal reinforcing layer and the semiconductor chip when the semiconductor chip is placed on the opening.

The metal reinforcing layer is, for example, an element for securing rigidity of the wiring circuit board.

The material of the metal reinforcing layer is not particularly limited, and examples thereof include Cu, Cu alloys, Al, stainless steel, FeNi alloys such as 42 alloys, and combinations thereof. Among them, Cu, Cu alloy, Al, and stainless steel are preferable from the viewpoint of thermal conductivity and electrical conductivity.

A thickness of the metal reinforcing layer is not particularly limited, and is, for example, 10 μm or more, preferably 15 μm or more, and is, for example, 100 μm or less, preferably 75 μm or less.

In the present invention, the “thickness” refers to the length of the metal reinforcing layer in the thickness direction. The thickness direction of the metal reinforcing layer refers to a direction orthogonal to a plane direction of the metal reinforcing layer.

The material of the insulating layer (for example, an insulating layer, a second insulating layer, a third insulating layer, a fourth insulating layer, and a fifth insulating layer) in the wiring structure layer is not particularly limited, and examples thereof include a synthetic resin. Examples of the synthetic resin include a polyimide resin, an epoxy resin, polyether nitrile, polyether sulfone, polyethylene terephthalate, polyethylene naphthalate, and polyvinyl chloride. From the viewpoint of excellent heat resistance, low linear expansion coefficient, and excellent withstand voltage, a polyimide resin and an epoxy resin are preferable.

The insulating layer may or may not contain a filler, but when the insulating layer does not contain a filler, the insulating layer is excellent in insulating properties and excellent in suppression of electrical leakage.

The insulating layer may or may not contain glass fiber. The insulating layer containing the glass fiber is formed by impregnating a glass fiber cloth with a synthetic resin like glass epoxy represented by FR4 (Flame Retardant Type 4).

The thickness of the insulating layer is not particularly limited, and is, for example, 1 μm or more, preferably 3 μm or more, and is, for example, 35 μm or less, preferably 20 μm or less.

Examples of the material of the wiring layer (for example, a wiring layer, a second wiring layer, a third wiring layer, and a fourth wiring layer) in the wiring structure layer include a metal material. Examples of the metal material include copper, nickel, gold, solder, and alloys thereof.

The thickness of the wiring layer is not particularly limited, and is, for example, 3 μm or more, preferably 5 μm or more, and is, for example, 50 μm or less, preferably 30 μm or less.

The wiring structure layer may include a seed layer (not illustrated). The seed layer is used as a conductive layer for electrolytic plating.

Examples of the material of the seed layer include copper, chromium, nickel, and alloys thereof.

The metal reinforcing layer may have an opening other than the opening for enabling the semiconductor chip to be connected to the wiring circuit board. Such an opening is, for example, an opening penetrating the metal reinforcing layer in the thickness direction. Such an opening is formed, for example, in order to reduce warpage of the wiring structure layer.

Further, the metal reinforcing layer may have a second opening and a third opening as openings other than the opening (first opening) for enabling the semiconductor chip to be connected to the wiring circuit board. Such an opening is, for example, an opening penetrating the metal reinforcing layer in the thickness direction. Such an opening is formed, for example, in order to reduce warpage of the wiring structure layer.

For example, the second opening and the third opening are formed so as to sandwich the first opening in an arbitrary cross section (X) in the thickness direction of the metal reinforcing layer. This embodiment will be described later with reference to FIGS. 2A and 2B.

A part of the wiring layer may be exposed as a terminal at the second opening.

A part of the wiring layer may be exposed as a terminal at the third opening.

In an example of the wiring circuit board, the metal reinforcing layer does not have an opening penetrating the metal reinforcing layer in the thickness direction in a cross section (Y) that is a cross section in the thickness direction of the metal reinforcing layer and is orthogonal to the cross section (X).

This embodiment will be described later with reference to FIGS. 2A to 2C.

In another example of the wiring circuit board, the metal reinforcing layer has a fourth opening in addition to the opening (first opening), the second opening, and the third opening. The fourth opening is an opening penetrating the metal reinforcing layer in the thickness direction.

In this example, the fourth opening is formed such that the cross section (Y) in the thickness direction of the metal reinforcing layer, the cross section (Y) being orthogonal to the cross section (X), includes the fourth opening.

In another example of the wiring circuit board, the metal reinforcing layer has a fourth opening and a fifth opening in addition to the opening (first opening), the second opening, and the third opening. The fourth opening and the fifth opening are openings that penetrate the metal reinforcing layer in the thickness direction.

For example, the fourth opening and the fifth opening are formed such that the cross section (Y) in the thickness direction of the metal reinforcing layer, the cross section (Y) being orthogonal to the cross section (X), includes the fourth opening and the fifth opening.

The fourth opening and the fifth opening are formed so as to sandwich the first opening in the cross section (Y), for example. This embodiment will be described later with reference to FIGS. 3A to 3C.

A part of the wiring layer may be exposed as a terminal at the fourth opening.

A part of the wiring layer may be exposed as a terminal at the fifth opening.

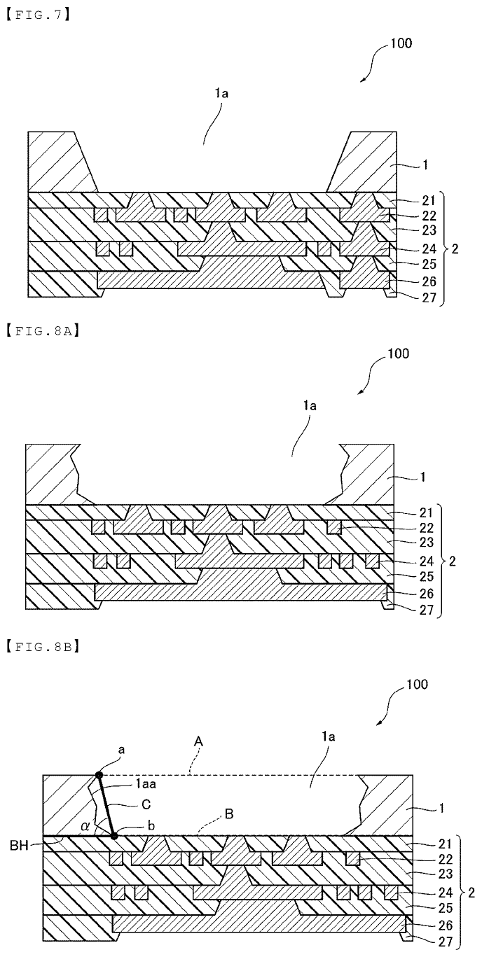

The wiring structure layer may include another insulating layer other than the insulating layer and another wiring layer other than the wiring layer in the opening of the metal reinforcing layer. This embodiment will be described later with reference to FIGS. 5 and 6.

The wiring structure layer may not have another insulating layer other than the insulating layer and another wiring layer other than the wiring layer in the opening of the metal reinforcing layer. Examples of this embodiment include the embodiments illustrated in FIGS. 1A and 1B.

FIGS. 2A to 2C illustrate another example of the wiring circuit board.

FIG. 2A is a top view of an example of the wiring circuit board.

FIG. 2B is a cross-sectional view taken along line X-X of FIG. 2A. The X-X cross section is a cross section orthogonal to the side of the opening 1a.

FIG. 2C is a cross-sectional view taken along line Y-Y of FIG. 2A. The Y-Y cross section is a cross section orthogonal to the X-X cross section. The Y-Y cross section is a cross section orthogonal to the side of the opening 1a.

In the wiring circuit board 100 illustrated in FIGS. 2A to 2C, the metal reinforcing layer 1 has a second opening 1b and a third opening 1c in addition to the opening 1a. As illustrated in FIG. 2B, the second opening 1b penetrates the metal reinforcing layer 1 in the thickness direction. As illustrated in FIG. 2B, the third opening 1c penetrates the metal reinforcing layer 1 in the thickness direction.

In FIG. 2A, the opening 1a has a substantially rectangular shape in top view. In FIG. 2A, four corners of the rectangle are chamfered, but the four corners may be right angles.

In the cross-sectional view taken along line X-X in FIG. 2B, the second opening 1b and the third opening 1c are formed so as to sandwich the opening 1a.

In addition, in the cross-sectional view taken along line Y-Y of FIG. 2C, the metal reinforcing layer 1 does not have an opening penetrating the metal reinforcing layer 1 in the thickness direction.

As illustrated in FIG. 2B, in the wiring structure layer 2, a part of the wiring layer 22 may be exposed as a terminal at the second opening 1b and the third opening 1c.

FIGS. 3A to 3C illustrate another example of the wiring circuit board.

FIG. 3A is a top view of an example of the wiring circuit board.

FIG. 3B is a cross-sectional view taken along line X-X of FIG. 3A. The X-X cross section is a cross section orthogonal to the side of the opening 1a.

FIG. 3C is a cross-sectional view taken along line Y-Y of FIG. 3A. The Y-Y cross section is a cross section orthogonal to the X-X cross section. The Y-Y cross section is a cross section orthogonal to the side of the opening 1a.

In the wiring circuit board 100 illustrated in FIGS. 3A to 3C, the metal reinforcing layer 1 has a second opening 1b, a third opening 1c, a fourth opening 1d, and a fifth opening 1e in addition to the opening 1a. As illustrated in FIG. 3B, the second opening 1b penetrates the metal reinforcing layer 1 in the thickness direction. As illustrated in FIG. 3B, the third opening 1c penetrates the metal reinforcing layer 1 in the thickness direction. As illustrated in FIG. 3C, the fourth opening 1d penetrates the metal reinforcing layer 1 in the thickness direction. As illustrated in FIG. 3C, the fifth opening 1e penetrates the metal reinforcing layer 1 in the thickness direction.

In FIG. 3A, the opening 1a has a substantially rectangular shape in top view. In FIG. 3A, four corners of the rectangle are chamfered, but the four corners may be right angles.

In the cross-sectional view taken along line X-X in FIG. 3B, the second opening 1b and the third opening 1c are formed so as to sandwich the opening 1a.

In the cross-sectional view taken along line Y-Y of FIG. 3C, the fourth opening 1d and the fifth opening 1e are formed so as to sandwich the opening 1a.

As illustrated in FIGS. 3B and 3C, in the wiring structure layer 2, a part of the wiring layer 22 may be exposed as a terminal at the second opening 1b, the third opening 1c, the fourth opening 1d, and the fifth opening 1e.

An area of the openings in the metal reinforcing layer is not particularly limited, but the area of all the openings when the metal reinforcing layer is viewed from the thickness direction (when viewed from the top) is preferably 60% to 99% and more preferably 70% to 95% of the total area of the metal reinforcing layer when the metal reinforcing layer is viewed from the thickness direction. The lower limit or more is advantageous in that a semiconductor chip having a larger size can be placed, and the upper limit or less is advantageous in terms of prevention of warpage.

The area of all the openings when the metal reinforcing layer is viewed from the thickness direction (when viewed from the top) is the total opening area of the opening 1a, the second opening 1b, and the third opening 1c in the case of FIG. 2A. The total area of the metal reinforcing layer when the metal reinforcing layer is viewed from the thickness direction is the total area of the metal reinforcing layer including the opening 1a, the second opening 1b, and the third opening 1c in the case of FIG. 2A.

A method for manufacturing the wiring circuit board according to the present invention includes a step of forming an opening penetrating the metal reinforcing layer in a thickness direction of the metal reinforcing layer in the metal reinforcing layer.

The step of forming the opening includes forming the opening such that the angle (α) is less than 90°.

The method for forming the opening so that the angle (α) is less than 90° is not particularly limited, and examples thereof include etching. Examples of the etching include wet etching.

Examples of the method for forming the opening by the wet etching include the following methods (1) to (4).
(1) Formation of photoresist film on surface of metal reinforcing layer on side opposite to wiring structure layer side
(2) Formation of resist pattern by selective exposure and development on photoresist film (partial exposure of metal reinforcing layer)
(3) Wet etching on exposed metal reinforcing layer (for example, wet etching using ferric chloride)
(4) Removal of photoresist film

Examples of the method for controlling the angle (α) include a method in which the angle (α) is controlled by a spray pressure when the metal reinforcing layer is wet-etched by a spray method. For example, the angle (α) can be reduced by reducing the spray pressure.

In the method for manufacturing the wiring circuit board, the method for forming the wiring structure layer is not particularly limited.

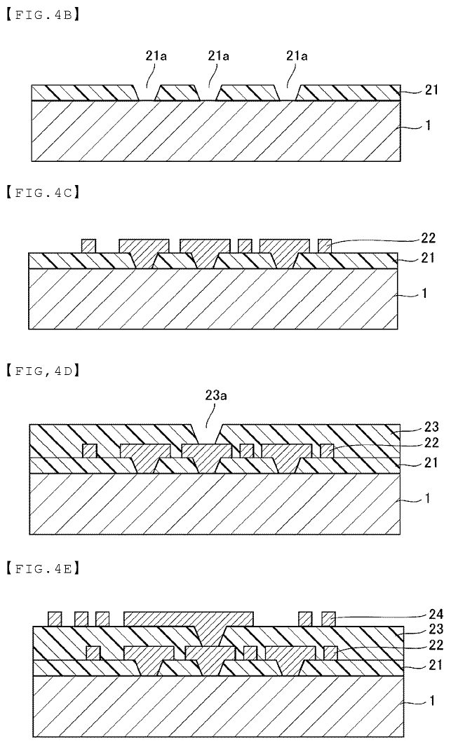

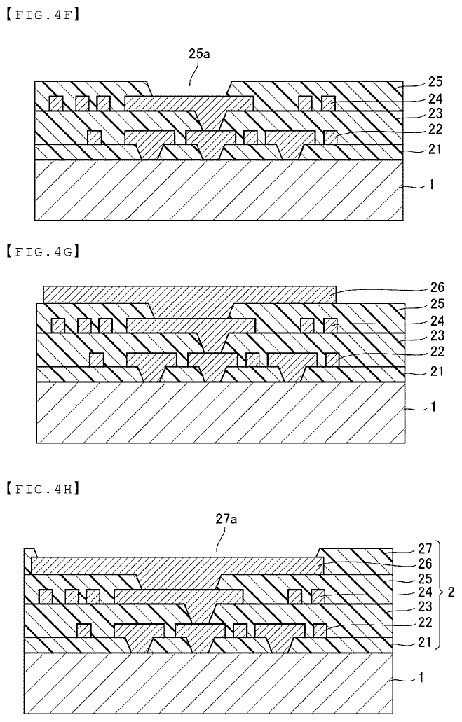

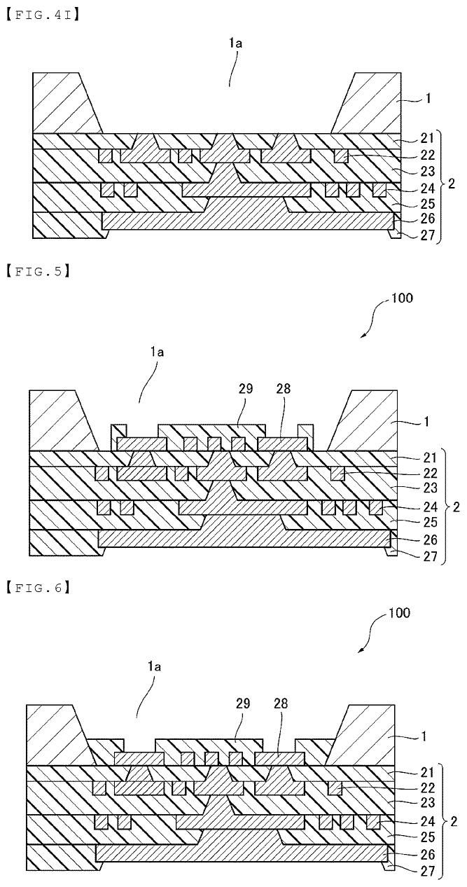

An embodiment of the method for manufacturing the wiring circuit board illustrated in FIGS. 1A and 1B will be described with reference to FIGS. 4A to 4I.

First, the metal reinforcing layer 1 is prepared (FIG. 4A).

Next, the insulating layer 21 having the through hole 21a is formed on one surface of the metal reinforcing layer 1 (FIG. 4B). The insulating layer 21 having the through hole 21a can be formed, for example, as follows.
Application and drying of photosensitive resin composition containing photosensitive polyimide
Selective exposure and development on formed photosensitive polyimide film

Next, the patterned wiring layer 22 is formed on the insulating layer 21 and in the through hole 21a (FIG. 4C). The wiring layer 22 can be formed, for example, as follows.
Formation of seed layer (not illustrated) on insulating layer 21
Formation of photoresist film (not illustrated) on seed layer
Formation of resist pattern by selective exposure and development on photoresist film (partial exposure of seed layer)
Plating on exposed seed layer
Removal of photoresist film and removal of unnecessary seed layer

Thus, the patterned wiring layer 22 is formed. A part of the wiring layer 22 fills the through hole of the insulating layer 21.

Next, the second insulating layer 23 having the through hole 23a is formed on the wiring layer 22 (FIG. 4D). The second insulating layer 23 covers the patterned wiring layer 22. The second insulating layer 23 can be formed by, for example, applying and drying a photosensitive resin composition containing a photosensitive polyimide, and selectively exposing and developing the formed photosensitive polyimide film.

Next, the patterned second wiring layer 24 is formed on the second insulating layer 23 and in the through hole 23a (FIG. 4E). The second wiring layer 24 can be formed, for example, as follows.
Formation of seed layer (not illustrated) on second insulating layer 23
Formation of photoresist film (not illustrated) on seed layer
Formation of resist pattern by selective exposure and development on photoresist film (partial exposure of seed layer)
Electrolytic plating on exposed seed layer
Removal of photoresist film and removal of unnecessary seed layer

The formed patterned electrolytic plating layer becomes the second wiring layer 24.

Thus, the patterned second wiring layer 24 is formed. A part of the second wiring layer 24 fills the through hole of the second insulating layer 23.

Next, the third insulating layer 25 having the through hole 25a is formed on the second wiring layer 24 (FIG. 4F). The third insulating layer 25 covers the patterned second wiring layer 24. The third insulating layer 25 can be formed by, for example, applying and drying a photosensitive resin composition containing a photosensitive polyimide, and selectively exposing and developing the formed photosensitive polyimide film.

Next, the patterned third wiring layer 26 is formed on the third insulating layer 25 and in the through hole 25a (FIG. 4G). The third wiring layer 26 can be formed, for example, as follows.
Formation of seed layer (not illustrated) on third insulating layer 25
Formation of photoresist film (not illustrated) on seed layer
Formation of resist pattern by selective exposure and development on photoresist film (partial exposure of seed layer)
Electrolytic plating on exposed seed layer
Removal of photoresist film and removal of unnecessary seed layer

The formed patterned electrolytic plating layer becomes the third wiring layer 26.

Thus, the patterned third wiring layer 26 is formed. A part of the third wiring layer 26 fills the through hole of the third insulating layer 25.

Next, the fourth insulating layer 27 having the through hole 27a is formed on the third wiring layer 26 (FIG. 4H). The fourth insulating layer 27 covers the patterned third wiring layer 26. The fourth insulating layer 27 can be formed by, for example, applying and drying a photosensitive resin composition containing a photosensitive polyimide, and selectively exposing and developing the formed photosensitive polyimide film.

Thus, the wiring structure layer 2 is formed.

Next, the opening 1a is formed in the metal reinforcing layer 1 from the side of the metal reinforcing layer 1 opposite to the wiring structure layer 2 side (FIG. 4I). FIGS. 41 and 4H are views rotated by 180° relative to each other.

The opening 1a can be formed, for example, as follows.
Formation of photoresist film (not illustrated) on surface of metal reinforcing layer on side opposite to wiring structure layer side
Formation of resist pattern by selective exposure and development on photoresist film (partial exposure of metal reinforcing layer)
Wet etching on exposed metal reinforcing layer (for example, wet etching using ferric chloride)
Removal of photoresist film

Thus, the opening 1a is formed.

As described above, the wiring circuit board illustrated in FIGS. 1A and 1B is obtained.

Another example of the wiring circuit board will be described.

FIG. 5 is a schematic cross-sectional view of another example of the wiring circuit board.

The wiring circuit board 100 illustrated in FIG. 5 has the same structure as the wiring circuit board illustrated in FIGS. 1A and 1B except that the wiring structure layer 2 includes a fourth wiring layer 28 and a fifth insulating layer 29.

The wiring circuit board 100 illustrated in FIG. 5 includes the metal reinforcing layer 1 and the wiring structure layer 2.

The wiring structure layer 2 includes the fourth wiring layer 28 and the fifth insulating layer 29 in the opening 1a of the metal reinforcing layer 1.

The fourth wiring layer 28 has a pattern shape. The fifth insulating layer 29 covers the fourth wiring layer 28 while filling gaps in the pattern of the fourth wiring layer 28.

A part of the fourth wiring layer 28 is in electrical contact with a part of the wiring layer 22.

In the wiring circuit board 100 illustrated in FIG. 5, the fifth insulating layer 29 is not in contact with the metal reinforcing layer 1.

Examples of a method for forming the fourth wiring layer 28 and the fifth insulating layer 29 include the following methods.

After the wiring circuit board illustrated in FIG. 4I is manufactured, the fourth wiring layer 28 is formed in the opening 1a. The fourth wiring layer 28 can be formed, for example, by the following method.
Formation of seed layer (not illustrated) on insulating layer 21
Formation of photoresist film (not illustrated) on seed layer
Formation of resist pattern by selective exposure and development on photoresist film (partial exposure of seed layer)
Plating on exposed seed layer
Removal of photoresist film and removal of unnecessary seed layer

Thus, the patterned fourth wiring layer 28 is formed.

Next, the fifth insulating layer 29 having the through hole is formed on the fourth wiring layer 28. The fifth insulating layer 29 can be formed by, for example, applying and drying a photosensitive resin composition containing a photosensitive polyimide, and selectively exposing and developing the formed photosensitive polyimide film.

Another example of the wiring circuit board will be described.

FIG. 6 is a schematic cross-sectional view of another example of the wiring circuit board.

The wiring circuit board 100 illustrated in FIG. 6 has the same structure as the wiring circuit board illustrated in FIGS. 1A and 1B except that the wiring structure layer 2 includes a fourth wiring layer 28 and a fifth insulating layer 29.

The wiring circuit board 100 illustrated in FIG. 6 includes the metal reinforcing layer 1 and the wiring structure layer 2.

The wiring structure layer 2 includes the fourth wiring layer 28 and the fifth insulating layer 29 in the opening 1a of the metal reinforcing layer 1.

The fourth wiring layer 28 has a pattern shape. The fifth insulating layer 29 covers the fourth wiring layer 28 while filling gaps in the pattern of the fourth wiring layer 28.

A part of the fourth wiring layer 28 is in electrical contact with a part of the wiring layer 22.

In the wiring circuit board 100 illustrated in FIG. 6, the fifth insulating layer 29 is in contact with the metal reinforcing layer 1.

Another example of the wiring circuit board will be described.

FIG. 7 is a schematic cross-sectional view of another example of the wiring circuit board.

The wiring circuit board 100 illustrated in FIG. 7 has the same structure as the wiring circuit board illustrated in FIGS. 1A and 1B except that the wiring structure layer 2 has a thermal via.

In the wiring circuit board 100 illustrated in FIG. 7, a part of the wiring layer 22, a part of the second wiring layer 24, and a part of the third wiring layer 26 are connected to form the thermal via. The thermal via is connected to the metal reinforcing layer 1. For example, the heat generated in the wiring structure layer 2 is conducted to the metal reinforcing layer 1 via the thermal via, whereby the heat generated in the wiring structure layer 2 can be dissipated.

Another example of the wiring circuit board will be described.

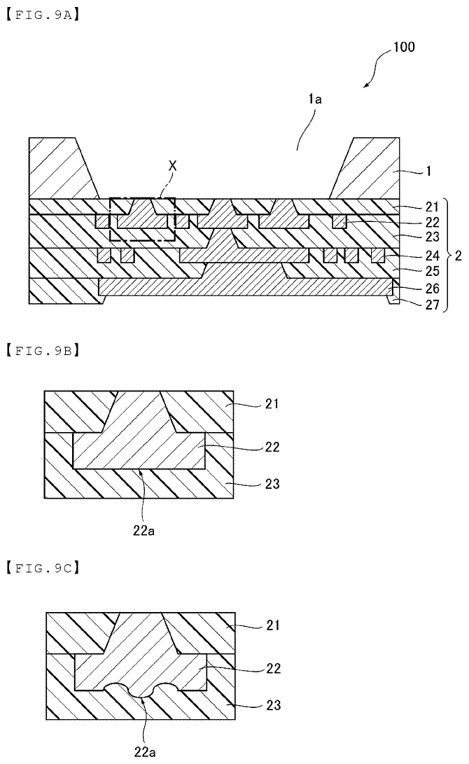

FIGS. 8A and 8B are schematic cross-sectional views of another example of the wiring circuit board.

The wiring circuit board 100 illustrated in FIGS. 8A and 8B has the same structure as the wiring circuit board illustrated in FIGS. 1A and 1B except that the shape of the side surface of the opening 1a is different from the shape of the side surface of the opening 1a in the wiring circuit board illustrated in FIGS. 1A and 1B.

The shape of the side surface of the opening 1a in the wiring circuit board illustrated in FIGS. 1A and 1B is linear in the cross section, whereas the shape of the side surface of the opening 1a in the wiring circuit board 100 illustrated in FIGS. 8A and 8B is non-linear in the cross section. Also in such a case, how to obtain the angle (α) is as follows.

In a case where, in a cross section in the thickness direction of the metal reinforcing layer 1, which includes the opening 1a,
a line which is a surface of the metal reinforcing layer 1 on a side opposite to the wiring structure layer 2 side is defined as a line (A),
a line which is a surface of the metal reinforcing layer 1 on the wiring structure layer 2 side is defined as a line (B),
an intersection of one side line 1aa of two side lines included in a shape of the opening 1a and the line (A) is defined as an intersection (a), an intersection of the one side line 1aa and the line (B) is defined as an intersection (b),
a line connecting the intersection (a) and the intersection (b) is defined as a line segment (C), and
a line of the line (B) on a side opposite to the opening 1a side with the intersection (b) as a start point is defined as a half line (BH),
an angle formed by the half line (BH) and the line segment (C) is defined as an angle (α).

Next, a structure example of the wiring layer will be described.

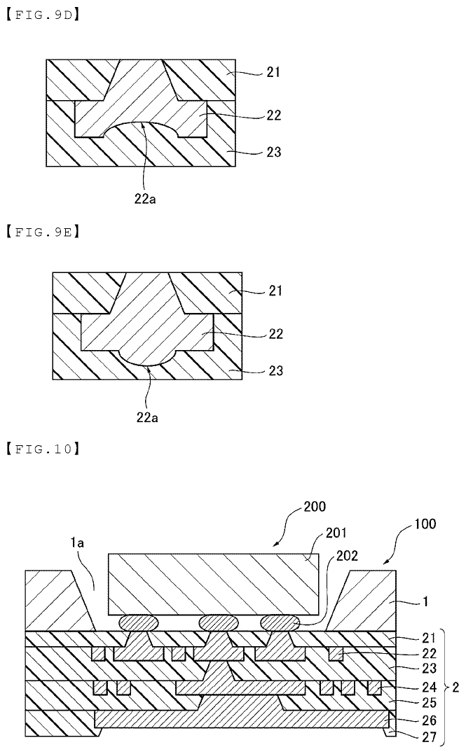

FIG. 9A is a schematic diagram of an embodiment of the wiring circuit board.

The wiring circuit board 100 illustrated in FIG. 9A has the same structure as the wiring circuit board illustrated in FIGS. 1A and 1B.

Structure examples of a region X in the wiring circuit board 100 illustrated in FIG. 9A are illustrated in FIGS. 9B to 9E.

In the structure example of the region X illustrated in FIG. 9B, a shape of a surface 22a of the wiring layer 22 on the side opposite to the through hole side of the insulating layer 21 is flat.

In the structure example of the region X illustrated in FIG. 9C, the shape of the surface 22a of the wiring layer 22 on the side opposite to the through hole side of the insulating layer 21 is a wave shape.

In the structure example of the region X illustrated in FIG. 9D, the shape of the surface 22a of the wiring layer 22 on the side opposite to the through hole side of the insulating layer 21 is a concave shape.

In the structure example of the region X illustrated in FIG. 9E, the shape of the surface 22a of the wiring layer 22 on the side opposite to the through hole side of the insulating layer 21 is a convex shape.

These shapes can be adjusted by, for example, the formation conditions of the wiring layer when the wiring layer 22 is formed so as to fill the through hole of the insulating layer 21. In particular, in a case where the wiring layer is formed by plating when the wiring layer 22 is formed so as to fill the through hole of the insulating layer 21, these shapes can be adjusted according to plating conditions such as a component of plating, a concentration of a plating solution, and a growth rate of plating.

The non-flat shape of the surface 22a of the wiring layer 22 as illustrated in FIGS. 9C to 9E may be referred to as a recess.

Next, an embodiment in which the semiconductor chip is connected to the wiring circuit board will be described.

FIG. 10 is a schematic cross-sectional view of an embodiment in which the semiconductor chip 200 is connected to the wiring circuit board 100.

The wiring circuit board 100 is the wiring circuit board illustrated in FIGS. 1A and 1B.

A semiconductor chip 200 includes a semiconductor chip body 201 and a solder ball 202.

The semiconductor chip 200 is placed in the opening 1a of the metal reinforcing layer 1 of the wiring circuit board 100, and a part of the wiring layer 22 filling the through hole of the insulating layer 21 is electrically connected to the solder ball 202.

The opening shape of the opening 1a of the wiring circuit board 100 is not particularly limited as long as the angle (α) is less than 90° and as long as the semiconductor chip body 201 is not in contact with the metal portion of the metal reinforcing layer 1.

For example, the wiring circuit board 100 to which the semiconductor chip 200 is connected is placed on another larger substrate, and then sealed with a sealing resin composition in order to protect the semiconductor chip and the wiring circuit board. At the time of sealing, when the angle (α) is less than 90°, the sealing resin composition can enter the gap between the edge of the opening 1a of the metal reinforcing layer 1 and the semiconductor chip, and after sealing, voids can be suppressed from remaining in the opening 1a of the metal reinforcing layer 1.

### (Semiconductor Package)

A semiconductor package of the present invention includes a wiring circuit board of the present invention.

The semiconductor package includes, for example, a semiconductor chip connected to a wiring circuit board.

The semiconductor package includes, for example, a sealing resin for sealing the semiconductor chip.

Examples of the semiconductor package include a flip chip-chip scale package (FC-CSP), a molded interconnect substrate-ball grid array (MIS-BGA) package, an embedded trace substrate-ball grid array (ETS-BGA) package, a fan-out type wafer level package (WLP), a fan-in type WLP, a fan-out type panel level package (PLP), a fan-in type PLP, a flip chip-ball grid array (FC-BGA) type, and high-end 2.5D and 3D packages.

### (Electronic Device)

An electronic device of the present invention includes a semiconductor package of the present invention.

The electronic device is not particularly limited, and examples thereof include ICT infrastructure devices such as servers, routers, supercomputers, mainframes, and workstations; antennas such as GPS antennas, antennas for wireless base stations, millimeter-wave antennas, and RFID antennas; communication devices such as mobile phones, smartphones, PHS, PDAs, and tablet terminals; digital devices such as personal computers, televisions, digital cameras, digital video cameras, POS terminals, wearable terminals, and digital media players; in-vehicle electronic devices such as electronic control system devices, in-vehicle communication devices, car navigation devices, millimeter-wave radars, and in-vehicle camera modules; semiconductor testing devices, and high-frequency measuring devices.

What is claimed is:

1. A wiring circuit board including a wiring structure layer having an insulating layer and a wiring layer, and a metal reinforcing layer in contact with one surface of the wiring structure layer, wherein
a surface of the metal reinforcing layer on a side opposite to the wiring structure layer side is exposed,
the metal reinforcing layer has an opening for enabling a semiconductor chip to be connected to the wiring circuit board, the opening penetrating the metal reinforcing layer in a thickness direction, and
in a case where, in a cross section in the thickness direction of the metal reinforcing layer, which includes the opening,
a line which is a surface of the metal reinforcing layer on a side opposite to the wiring structure layer side is defined as a line (A),
a line which is a surface of the metal reinforcing layer on the wiring structure layer side is defined as a line (B),
an intersection of one side line of two side lines included in a shape of the opening and the line (A) is defined as an intersection (a), an intersection of the one side line and the line (B) is defined as an intersection (b),
a line connecting the intersection (a) and the intersection (b) is defined as a line segment (C), and
a line of the line (B) on a side opposite to the opening side with the intersection (b) as a start point is defined as a half line (BH),
an angle (α) formed by the half line (BH) and the line segment (C) is less than 90°.

2. The wiring circuit board according to claim 1, wherein the angle (α) is 45° or more and less than 90°.

3. The wiring circuit board according to claim 1, wherein the metal reinforcing layer has a second opening penetrating the metal reinforcing layer in the thickness direction in addition to the opening.

4. The wiring circuit board according to claim 1, wherein
the metal reinforcing layer has a second opening and a third opening penetrating the metal reinforcing layer in the thickness direction in addition to the opening, and
the second opening and the third opening are formed so as to sandwich the opening in an arbitrary cross section (X) in the thickness direction of the metal reinforcing layer.

5. The wiring circuit board according to claim 4, wherein in a cross section (Y) that is a cross section in the thickness direction of the metal reinforcing layer and is orthogonal to the cross section (X), the metal reinforcing layer does not have an opening penetrating the metal reinforcing layer in the thickness direction.

6. The wiring circuit board according to claim 4, wherein
the metal reinforcing layer further has a fourth opening penetrating the metal reinforcing layer in the thickness direction, and
the fourth opening is formed such that a cross section (Y) in the thickness direction of the metal reinforcing layer, which is orthogonal to the cross section (X), includes the fourth opening.

7. The wiring circuit board according to claim 1, wherein the wiring structure layer includes an insulating layer other than the insulating layer and a wiring layer other than the wiring layer in the opening of the metal reinforcing layer.

8. The wiring circuit board according to claim 1, wherein the wiring structure layer does not include an insulating layer other than the insulating layer and a wiring layer other than the wiring layer in the opening of the metal reinforcing layer.

9. A semiconductor package comprising the wiring circuit board according to claim 1.

10. An electronic device comprising the semiconductor package according to claim 9.

11. A wiring circuit board manufacturing method for manufacturing the wiring circuit board according to claim 1, the wiring circuit board manufacturing method comprising:
a step of forming the opening penetrating the metal reinforcing layer in the thickness direction in the metal reinforcing layer, wherein
the step of forming the opening includes forming the opening such that the angle (α) is less than 90°.

12. The wiring circuit board manufacturing method according to claim 11, wherein the step of forming the opening includes forming the opening by wet etching such that the angle (α) is less than 90°.
